(19) United States
(12) Patent Application Publication
(10) Pub. No.: US 2024/0284810 A1
(43) Pub. Date: Aug. 22, 2024

(54) MEMORY DEVICE AND METHOD FOR MANUFACTURING THE SAME

(71) Applicant: Nanyang Technological University, Singapore (SG)

(72) Inventors: Diing Shenp ANG, Singapore (SG); Haider ABBAS, Singapore (SG)

(73) Assignee: Nanyang Technological University, Singapore (SG)

(21) Appl. No.: 18/582,308

(22) Filed: Feb. 20, 2024

(30) Foreign Application Priority Data
Feb. 21, 2023 (SG) 10202300441S

(51) Int. Cl. H10N 70/00; H10B 63/00; H10N 70/20

(52) U.S. Cl. CPC H10N 70/8828; H10B 63/00; H10N 70/026; H10N 70/245

(57) ABSTRACT

According to embodiments of the present invention, a device or more specifically, a memory device is provided. The device includes a first electrode; a second electrode arranged opposite to the first electrode; and a transition-metal chalcogenide-based layer sandwiched between the first electrode and the second electrode, wherein the transition-metal chalcogenide-based layer is in direct contact with the first electrode and the second electrode. According to further embodiments of the present invention, a method for manufacturing the device is also provided.

### CROSS-REFERENCE TO RELATED APPLICATION

This application claims the benefit of priority of Singapore Patent Application No. 10202300441S, filed 21 Feb. 2023, the content of it being hereby incorporated by reference in its entirety for all purposes.

### TECHNICAL FIELD

Various embodiments relate to a device, more specifically, involving a memory device and a method for manufacturing the device.

### BACKGROUND

The information technology (IT) business has seen rapid growth in recent years, which is responsible for the generation of a vast amount of data every day. Consequently, the importance of high-quality memory for electronics applications has increased. Computing needs thus far have been met by three mainstream memory technologies, namely SRAM, DRAM and FLASH, conceived in the 1970s. These memory technologies rely on charge storage as a means for denoting distinct memory states. Although device scaling has improved the performance and memory density by leaps and bounds, it has become increasingly challenging to scale these charge-based memory technologies down to 10 nm and below. Due to reduced charge storage at nanoscale dimension, any charge loss significantly impacts performance and reliability. Therefore, there has been on-going research to develop alternative memory technologies with different operating principles. Thus far, three main candidates have emerged, namely spin-transfer-torque magnetoresistive random access memory (STT-MRAM), phase change random access memory (PCRAM) and resistive random-access memory (RRAM). Table 1 summarizes typical device characteristics of existing as well as emerging memory technologies.

TABLE 1
Device characteristics of existing and emerging memory technologies

| | Mainstream Memories | | | | Emerging Memories | | |
|---|---|---|---|---|---|---|---|
| | | | FLASH | | STT- | | |
| | SRAM | DRAM | NOR | NAND | MRAM | PCRAM | RRAM |
| Cell | >100F² | 6F² | 10F² | <4F² | 6~20F² | 4~20F² | <4F² if |
| Area | | | | (3D) | | | 3D |
| Multi- | 1 | 1 | 2 | 3 | 1 | 2 | 2 |
| bit | | | | | | | |
| Voltage | <1 V | <1 V | >10 V | >10 V | <2 V | <3 V | <3 V |
| Read | ~1 ns | ~10 ns | ~50 ns | ~10 μs | <10 ns | <10 ns | <10 ns |
| Time | | | | | | | |
| Write | ~1 ns | ~10 ns | 10 μs- | 100 μs- | <5 ns | ~50 ns | <10 ns |
| Time | | | 1 ms | 1 ms | | | |
| Re- | N/A | ~64 ms | >10 | >10 | >10 | >10 | >10 |
| tention | | | years | years | years | years | years |
| Endur- | >1E16 | >1E16 | >1E5 | >1E4 | >1E15 | >1E9 | >1E6~ |
| ance | | | | | | | 1E12 |
| Write | ~fJ | ~10 fJ | 100 pJ | ~10 fJ | ~0.1 pJ | ~10 pJ | ~0.1 pJ |
| Energy | | | | | | | |
| (J/bit) | | | | | | | |

F: feature size of lithography, and the energy estimation is on the cell-level (not the array-level)

Like existing mainstream memory technologies, the characteristics of emerging memory technologies differ significantly from one another, and no single candidate can satisfy the following set of characteristics of an ideal universal memory: sub-ns write/read speed, sub-1 V logic-compatible operating voltage, ˜fJ/bit energy consumption, long retention (>10 years) and scalability (<10 nm). Therefore, it is important to clarify that each emerging memory technology has its own target application space. For example, RRAM has excellent scalability (<4F² with 3D integration) but relatively poor endurance compared to STT-MRAM. It is therefore suitable for replacing high-density FLASH. On the other hand, STT-MRAM has faster operating speed and better endurance, but a much larger footprint. Therefore, it is more suitable for substituting low-density SRAM.

RRAM may also serve as a new storage class memory (SCM) sandwiched between DRAM and FLASH in the memory hierarchy. SCM is meant to bridge the gap between DRAM and FLASH by combining the advantages of the latter two and providing a low-cost yet high-speed intermediate memory platform that minimizes access to much slower secondary storage. RRAM, among other emerging memory technologies, offers potential for next-generation SCM due to its many technical benefits over existing charge-storage-based memories. More specifically, RRAM fits well into the SCM category because it offers low operating voltage and latency (which FLASH is not able to), non-volatile multibit storage and block-level access (which DRAM is not able to). RRAM may be targeted at SCM applications. RRAM may be preferred over PCRAM because of the former's more favorable characteristics in terms of footprint, programming speed and energy consumption.

To achieve large-scale integration, considerable device optimizations are still needed. In order to initiate switching in pristine devices, a soft-breakdown procedure (electroforming) with a higher voltage is typically required. This high-voltage forming process can damage pre-formed cells in a passive crossbar array. Additionally, external compliance current (CC) is required to prevent irreversible device breakdown caused by current overshoot during the SET process, that is ineffective given the fabrication of scalable passive crossbar array devices. For greater scalability and device reliability, the fabrication of self-compliance and forming-free devices is required. Several critical issues also need to be resolved before widespread adoption of RRAM can happen.

One such issue is variability, which refers to deviation, from cycle to cycle (C2C) and device to device (D2D), in the write/erase voltages needed to effect a change in memory state and the resistance values that represent different memory states. RRAM exhibits significant variability because it relies on inherently stochastic formation/dissolution of minute conducting paths embedded in a semiconducting matrix for denoting the storage of distinct memory states. Variability may be mitigated using write/verify operation, a circuit-level measure that repeatedly adjusts the programming condition such that the desired memory state is reached within an acceptable tolerance. However, this erodes the benefits of RRAM (low energy consumption and high operating speed). Therefore, a radical solution is to reduce variability at device level.

For SCM applications which involve frequent updating of information, the RRAM requires good endurance, that is a measure of its ability to withstand a certain number of write/erase cycles before failure occurs. With architectural wear-level techniques, the acceptable endurance is ˜109 cycles for gigabit data rate. The calculation assumes a 1.6 Gb/s data rate, all write events, a useful life of 10 years (˜3×10⁸ s) and a 1 Gb RRAM array with 10% wear-leveling. This endurance performance is not widely demonstrated. For example, a study based on the Ta₂O₅₋ₓ/TaO₂₋ₓ structure reported an endurance of 10¹² cycles but this is not widely shown by other studies based on similar material systems.

The reported direct current (DC) set/reset voltages, that are needed to effect a change in memory state, are typically in the range of 1-3 V for RRAM. Under pulse (actual operating) condition, higher voltages are required, that may be detrimental to endurance reliability. An operating voltage of less than 1 V may be desired, that also allows easy integration with logic circuitry.

Filamentary RRAM, where a nano-sized conductive filament (CF) is formed/ruptured in a semiconducting/insulating layer, offers high scalability. RRAM devices may be classified into two main categories, namely oxide-based valence-change RAM (or OxRAM) and conductive-bridge RAM (or CBRAM). Hybrid CF involving these two categories also exists. The OxRAM device relies on the formation/rupture of a CF made of vacancy defects in an oxide material (typically) to achieve memory operation. It has a good endurance (>10⁶ cycles generally) and may be programmed to different intermediate memory states easily as state transition is gradual. But only a select few (e.g., TaOₓ/Ta₂O₅-based OxRAM) have shown endurance>10⁹ cycles. Moreover, its small memory window (˜10-10²) coupled with switching variability do not allow multi-bit storage to be realized reliably in a single device. On the other hand, the CBRAM device depends on the formation/dissolution of a metallic filament within a semiconducting matrix for different memory state representations. CBRAM, where formation/rupture of metallic CFs provides switching, is one promising candidate for SCM due to its low power consumption, low operating voltages, facile and scalable fabrication, and fast switching speed. The CBRAM device has a larger memory window (>10⁵) and lower operating voltage, but poorer endurance (<10⁶ cycles) compared to the OxRAM device. Although the memory window is larger, multi-bit memory storage is not easily implemented because memory state transition is abrupt and thus it is difficult to reliably switch to a particular memory state, considering that switching also varies substantially in the case of CBRAM as well.

Thus, there is a need for a device that paves the way for the development of CBRAM technology for scalable high-density SCM, while addressing at least the problems discussed above.

### SUMMARY

According to an embodiment, a device, more specifically, involving a memory device is provided. The device may include a first electrode; a second electrode arranged opposite to the first electrode; and a transition-metal chalcogenide-based layer sandwiched between the first electrode and the second electrode, wherein the transition-metal chalcogenide-based layer is in direct contact with the first electrode and the second electrode.

According to an embodiment, a method for manufacturing a device, more specifically, involving a memory device is provided. The method may include providing a first electrode; depositing a transition-metal chalcogenide material on the first electrode to form a transition-metal chalcogenide-based layer over the first electrode; and depositing an electrically conductive material on the transition-metal chalcogenide-based layer to form a second electrode and to sandwich the transition-metal chalcogenide-based layer between the first electrode and the second electrode. The transition-metal chalcogenide-based layer may be in direct contact with the first electrode and the second electrode.

### BRIEF DESCRIPTION OF THE DRAWINGS

In the drawings, like reference characters generally refer to like parts throughout the different views. The drawings are not necessarily to scale, emphasis instead generally being placed upon illustrating the principles of the invention. In the following description, various embodiments of the invention are described with reference to the following drawings, in which:

FIG. 1 shows a schematic side view of a device, according to various embodiments.

FIG. 2 shows a flow chart illustrating a method for manufacturing a device, according to various embodiments.

FIG. 3 shows a graph illustrating I-V characteristics of an Ag/WTe₂/Pt device measured at CC level being 1 mA, according to one example.

FIG. 4 shows a graph illustrating I-V characteristics of the Ag/WTe₂/Pt device measured at CC level being 5 mA, according to one example.

FIG. 5 shows a graph illustrating I-V characteristics of the Ag/WTe₂/Pt device measured with CC-free and self-limiting behaviour, according to one example.

FIG. 6 shows a graph illustrating a relationship between current and cycle number to reflect DC endurance characteristics of the Ag/WTe₂/Pt device at different CC levels, according to one example.

FIG. 7 shows a graph illustrating the cumulative probability distribution of high resistance states (HRS) and low resistance states (LRS) of the device at different CC levels, according to one example.

FIG. 8 shows a graph illustrating box plots of VSET and VRESET for the device at different CC levels, according to one example.

FIG. 9 shows a graph illustrating plots of LRS and HRS currents from 100 devices to depict D2D variations, according to various examples.

FIG. 10 shows a graph illustrating plots of VSET and VRESET from the 100 devices to depict D2D variations, according to various examples.

FIG. 11 shows a graph illustrating the relationships between LRS current and HRS current with respect to the number of pulses to depict the pulse endurance characteristics of the device, according to an example.

FIG. 12 shows a graph illustrating plots of LRS current and HRS current at different temperatures with respect to time to depict the retention characteristics of the device, according to an example.

FIG. 13 shows a graph illustrating accelerated retention test of the device, according to one example.

FIG. 14 shows a graph illustrating the relationships between LRS current and HRS current with respect to the number of pulses to depict the pulse endurance characteristics of 10 sample devices.

FIG. 15 shows a graph illustrating the I-V characteristics of the device presenting multilevel switching controlled by varying RESET sweep voltage, according to an example.

FIG. 16 shows a graph illustrating the relationships between the currents of multilevels with respect to the number of pulses to depict the pulse endurance characteristics of multibit memory in 10 sample devices.

FIG. 17 shows a graph illustrating plots of the currents of multilevels over time, to depict the retention characteristics of the multibit memory states, according to an example.

FIG. 18 shows a graph illustrating a voltage-vs-time plot and a current-vs-time plot of the device, with SET being a 50 ns pulse with +1 V pulse amplitude, according to one example.

FIG. 19 shows a graph illustrating a voltage-vs-time plot and a current-vs-time plot of the device, with RESET being a 50 ns pulse with −1 V pulse amplitude, according to one example.

FIG. 20 shows a graph illustrating a LRS current over time to depict the LRS retention of the device, according to one example.

### DETAILED DESCRIPTION

The following detailed description refers to the accompanying drawings that show, by way of illustration, specific details, and embodiments in which the invention may be practiced. These embodiments are described in sufficient detail to enable those skilled in the art to practice the invention. Other embodiments may be utilized and structural, logical, and electrical changes may be made without departing from the scope of the invention. The various embodiments are not necessarily mutually exclusive, as some embodiments can be combined with one or more other embodiments to form new embodiments.

Embodiments described in the context of one of the methods or devices are analogously valid for the other methods or devices. Similarly, embodiments described in the context of a method are analogously valid for a device, and vice versa.

Features that are described in the context of an embodiment may correspondingly be applicable to the same or similar features in the other embodiments. Features that are described in the context of an embodiment may correspondingly be applicable to the other embodiments, even if not explicitly described in these other embodiments. Furthermore, additions and/or combinations and/or alternatives as described for a feature in the context of an embodiment may correspondingly be applicable to the same or similar feature in the other embodiments.

In the context of various embodiments, the articles “a”, “an” and “the” as used with regard to a feature or element include a reference to one or more of the features or elements.

In the context of various embodiments, the phrase “at least substantially” may include “exactly” and a reasonable variance.

In the context of various embodiments, the term “about” or “approximately” as applied to a numeric value encompasses the exact value and a reasonable variance.

As used herein, the term “and/or” includes any and all combinations of one or more of the associated listed items.

As used herein, the expression “configured to” may mean “constructed to” or “arranged to”.

Various embodiments provide highly repeatable and reliable performance of Conductive Bridge Random Access Memory (CBRAM), in particular, WTe₂-based CMRAM device. The WTe₂-based CMRAM device may be forming-free and self-compliance with highly uniform multilevel switching for high-density memory.

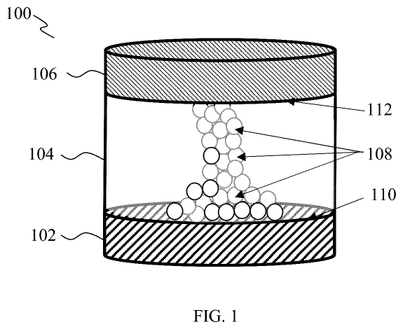

FIG. 1 shows a schematic side view of a device 100, according to various embodiments. The device 100 may include a first electrode 102; a second electrode 106 arranged opposite to the first electrode 102; a transition-metal chalcogenide-based layer 104 sandwiched between the first electrode 102 and the second electrode 106, wherein the transition-metal chalcogenide-based layer 104 is in direct contact with the first electrode 102 and the second electrode 106.

The transition-metal chalcogenide-based layer 104, providing an electrolyte of transition-metal chalcogenide material 108, may be an amorphous tungsten ditelluride (WTe₂) layer.

In other words, the amorphous WTe₂ layer may include a first surface 110; and a second surface 112 opposite the first surface 110, wherein the first surface 110 is in direct contact with the first electrode 102 and the second surface 112 is in direct contact with the second electrode 106. There is absence of any other material layers of electrolyte, apart from the transition-metal chalcogenide-based layer 104, e.g. the amorphous WTe₂ layer between the first and second electrodes 102, 106. For example, a single layer of WTe₂ electrolyte may be solely provided between the first electrode 102 and the second electrode 106.

In various embodiments, the amorphous WTe₂ layer may have a thickness ranging from 10 nm to 15 nm, or preferably, of about 12 nm.

The first electrode 102 may include an inert metal. For example, the inert metal may include platinum (Pt) or palladium (Pd). The second electrode 106 may include an electrochemically active metal. For example, electrochemically active metal may include silver (Ag) or copper (Cu).

Each of the first electrode 102 and the second electrode 106 may have a thickness (or height) ranging between 50 nm to 100 nm, or preferably of about 70 nm. The working thickness range of each of the first electrode 102 and the second electrode 106 may have a lower limit less than 50 nm and an upper limit larger than 100 nm. In some embodiments, the first electrode 102 and the second electrode 106 may have the same thickness. In other embodiments, the first electrode 102 and the second electrode 106 may have different thicknesses.

In various embodiments, the device 100 may include a substrate coupled to the first electrode 102. For example, the substrate may include a SiO₂/Si substrate. Other substrates may be used for the device fabrication, e.g. glass for a transparent device, or polyethylene terephthalate (PET) for a flexible device.

The device 100 may include an adhesion layer arranged between the substrate and the first electrode 102. For example, the adhesion layer may include titanium or chromium. The adhesion layer may have a thickness (or height) of about 10 nm.

The device 100 may be of a 3-dimensional shape with an elongated body and two flat sides. For example but not limiting to, the device 100 may be of cylindrical, or cuboidal in shape. In various embodiments, the device 100 may have a cell structure with a diameter of about 100 μm or less.

The device 100 may include a chalcogenide-based conductive-bridge random access memory (CBRAM) device. For example, the device 100 may be a standalone chalcogenide-based CBRAM device, or a crossbar array comprising a selector device and a chalcogenide-based CBRAM device.

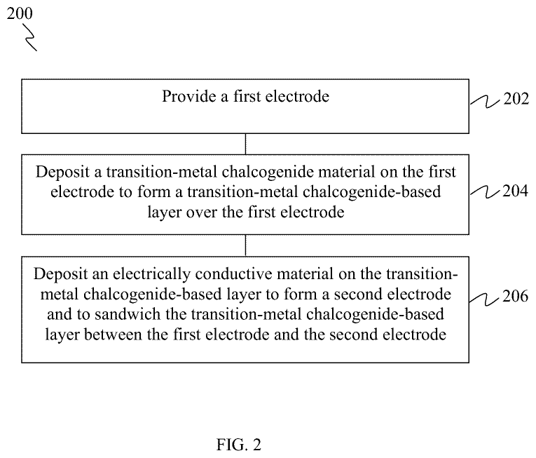

FIG. 2 shows a flow chart illustrating a method 200 for manufacturing a device (e.g. 100 of FIG. 1), according to various embodiments. In Step 202 of the method 200, a first electrode (e.g. 102 of FIG. 1) may be provided. In Step 204, a transition-metal chalcogenide material (e.g. 108 of FIG. 1) may be deposited on the first electrode to form a transition-metal chalcogenide-based layer (e.g. 104 of FIG. 1) over the first electrode. In Step 206, an electrically conductive material may be deposited on the transition-metal chalcogenide-based layer to form a second electrode (e.g. 106 of FIG. 1) and to sandwich the transition-metal chalcogenide-based layer between the first electrode and the second electrode. The transition-metal chalcogenide-based layer may be in direct contact with the first electrode and the second electrode. For example, the first electrode may include platinum and the second electrode may include silver.

In the context of various embodiments, it should be understood and appreciated that a material “deposited on” a surface (or another material) may mean the material laid on or over at least part of the surface. A layer “formed over” a surface may mean that the layer covers the surface either in part(s) or in entirety.

The method 200 may include the same or like elements or components as those of the devices 100 of FIG. 1, and as such, the like elements may be as described in the context of the device of FIG. 1, and therefore some corresponding descriptions are omitted here.

In various embodiments, the step of depositing the transition-metal chalcogenide material on the first electrode at Step 204 may include depositing tungsten ditelluride to form an amorphous WTe₂ layer over the first electrode. For example, depositing the WTe₂ may include performing radio frequency (RF) sputtering of WTe₂ on the first electrode.

The method 200 may further include coupling a substrate to the first electrode. For example, coupling the substrate to the first electrode may include depositing an adhesion layer on the substrate; and thermally evaporating another electrically conductive material over the adhesion layer to form the first electrode. For example, depositing the adhesion layer may include performing direct current (DC) sputtering of an adhesion material on the substrate. The adhesion layer may include titanium.

In various embodiments, depositing the electrically conductive material on the transition-metal chalcogenide-based layer to form the second electrode may include performing direct current (DC) sputtering of the electrically conductive material on the transition-metal chalcogenide-based layer. By performing the method 200, a single layer of WTe₂ electrolyte may be solely formed between the first electrode and the second electrode.

The method 200 may further include forming a cell structure of the device using a metal shadow mask having a diameter of about 100 μm or less, e.g. in the sub-micron ranges.

While the method described above is illustrated and described as a series of steps or events, it will be appreciated that any ordering of such steps or events are not to be interpreted in a limiting sense. For example, some steps may occur in different orders and/or concurrently with other steps or events apart from those illustrated and/or described herein. In addition, not all illustrated steps may be required to implement one or more aspects or embodiments described herein. Also, one or more of the steps depicted herein may be carried out in one or more separate acts and/or phases.

Examples of the device 100 and the method 200 will be described in more details below.

CBRAM devices based on WTe₂ transition metal chalcogenide solid electrolyte, as described in the same or similar context as the device 100 of FIG. 1, may be provided. The Ag/WTe₂/Pt CBRAM devices present excellent resistive switching characteristics and demonstrate forming-free as well as self-compliance switching with extremely high reliability in terms of endurance and retention characteristics. The devices also present highly uniform D2D and C2C switching, and this is highly desirable for practical implementation of RRAM devices in large crossbar arrays. Highly repeatable multilevel switching characteristics are further demonstrated for multibit storage. The WTe₂-based devices may pave the way for the development of CBRAM technology for scalable high-density SCM.

More specifically, an Ag/WTe₂/Pt CBRAM prototype device may feature sub-0.5 V DC set and reset voltages with extremely low cycle-to-cycle and device-to-device variability (˜±50 mV variation). The device also exhibits an endurance of >10⁷ cycles with no degradation in the low and high resistance state values and a 10-year retention lifetime at 72° C. at the pulse conditions used. The good retention performance provides sufficient room for further tradeoff with endurance. In addition, the device may be tuned to exhibit either abrupt or gradual memory state transition. The latter, in conjunction with low switching variability, enables reliable two-bit memory storage to be demonstrated with a memory window of just 10³. To the best of the inventors' knowledge, this is the first demonstration of a WTe₂-based CBRAM device with the above characteristics, and state of the art devices do not demonstrate low performance variability that match the WTe₂-based CBRAM device, according to various embodiments. Variability is a key obstacle which many other materials cannot overcome. The performance of the Ag/WTe₂/Pt CBRAM prototype device is compared with that of reported (existing) chalcogenide-based CBRAM devices, as shown in Table 2 below.

TABLE 2

| | Endurance | | V_{SET}/ | Multilevel | |
|---|---|---|---|---|---|
| Device Structure | (Cycles) | Retention | V_{RESET} (V) | Switching | Variability |
| Ag/GeS/Pt | 10⁵ | ~10⁵ s @25° C. | ~0.3/−0.6 | No | No D2D data; |
| | | | | | C2C data show |
| | | | | | ~0.5 V Δ (reset) |
| Ag/GeSe/Ni | 50 | — | ~0.15/−0.1 | No | No data |
| Ag/GeSe/Pt | 10⁵ | ~10⁵ s @85° C. | ~0.2/−0.4 | Yes | No data |
| Ag/Ag—GeTe/Ag | — | ~10⁵ s @25° C. | ~0.18/−0.1 | Yes | No D2D data; |
| | | | | | C2C data show |
| | | | | | 40 mV Δ |
| Cu/GeTe/TiN | ~10⁴ | ~10⁵ s @85° C. | ~−0.2/0.3 | No | No D2D data; |
| | | | | | C2C data show |
| | | | | | 0.3 V Δ |
| Cu/Ta/GeSe/TiN | ~10⁴ | 5 days | ~3.5/−2.7 | No | D2D data show |
| | | @150° C. | | | shows ~2-order |
| | | | | | Δ (HRS) |
| Ag/GeSbTe/TiN | 10² | ~10⁴ s @25° C. | ~1/−0.5 | No | No D2D data |
| Al/Cu/Ti/MoS₂/TiN | >1.5 × 10⁹ | — | ~0.55/−0.5 | No | No D2D data; |
| | | | | | C2C data |
| | | | | | show >1 V Δ |
| Ag/WTe₂/Pt | >2 × 10⁷ | 10 years | ~0.17/−0.16 | Yes | D2D data for |
| | | @72° C. | | | 100 devices, |
| | | | | | ~50 mV Δ |

### A. Prototype Structure and Fabrication

The prototype device structure may include a bottom electrode (BE) containing platinum (Pt), a top electrode (TE) comprising silver (Ag), and a layer of amorphous tungsten ditelluride (WTe₂) sandwiched between the BE and the TE.

The BE, TE, and the layer of WTe₂ may be described in similar context with the first electrode 102, the second electrode 106 and the transition-metal chalcogenide-based layer 104 of FIG. 1), respectively.

The devices (e.g. 100 of FIG. 1) were fabricated on a thermally oxidized Si substrate. First, a 10 nm thick Ti adhesion layer was deposited on top of the SiO₂/Si substrate by DC sputtering, followed by the thermal evaporation of a 70 nm thick Pt BE. A 12 nm thick WTe₂ electrolyte layer was deposited on Pt BE by RF sputtering. Finally, a 70 nm thick Ag TE was deposited by DC sputtering. The TE cells were defined using a metal shadow mask having a diameter of 100 μm for each device to form a device structure of Ag/WTe₂/Pt. As the fabrication process may be conventional, and Ag and Pt electrodes may used in other CBRAM devices, the good performance observed by the protoype devices is due to the WTe₂ chalcogenide.

A Keithley 4200-SCS parameter analyzer was used to conduct the DC and AC pulse measurements, with the bias applied to the Ag TE and the Pt BE grounded. The testing methods are conventional and have been applied on other RRAM devices.

### B. Results and Discussion

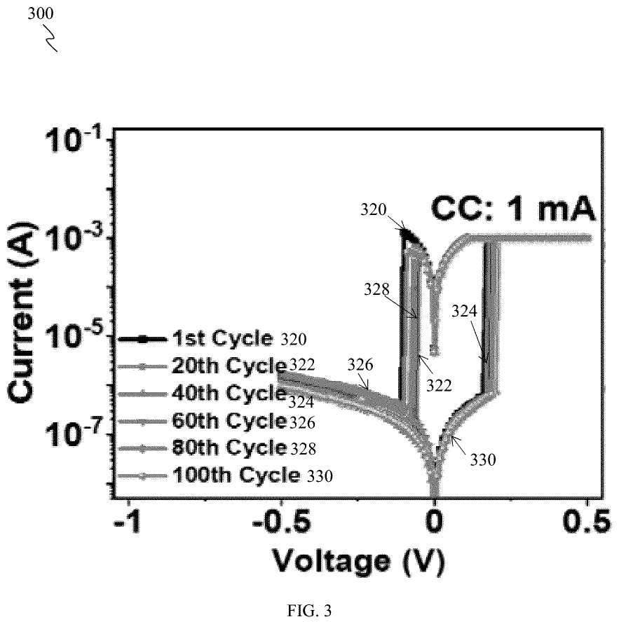

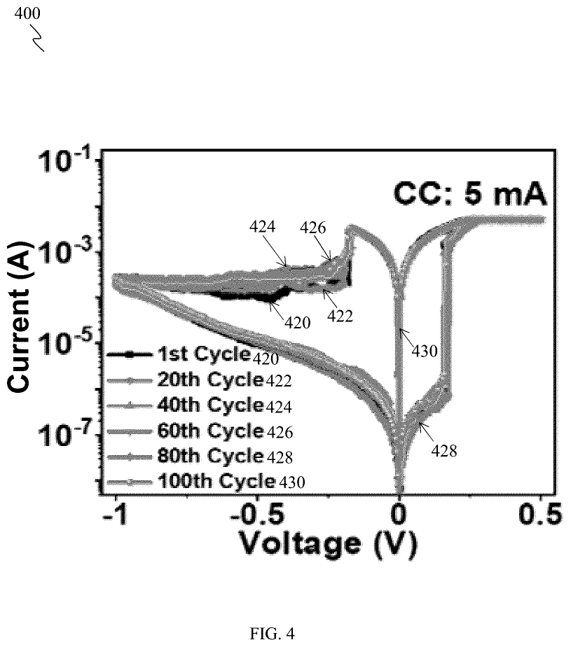

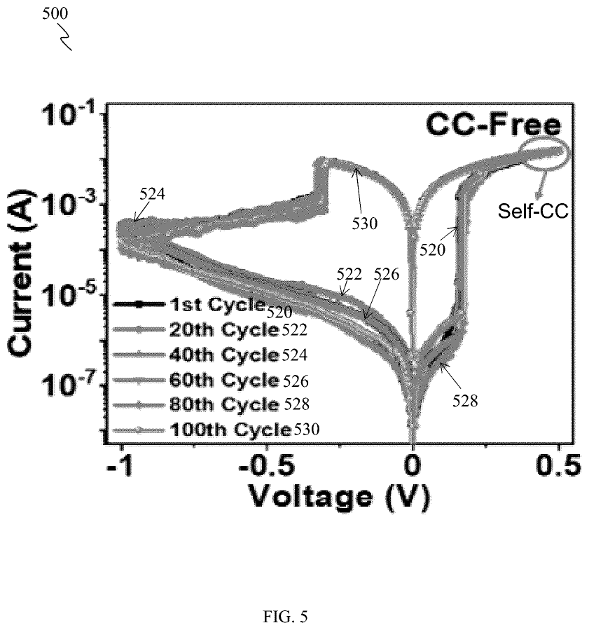

Typical current-voltage (I-V) characteristics of the Ag/WTe₂/Pt device (e.g. 100 of FIG. 1) measured at different current compliance (CC) levels and their corresponding DC endurance characteristics are shown in FIGS. 3 to 6. More specifically, FIG. 3 shows a graph 300 illustrating I-V characteristics of the Ag/WTe₂/Pt device measured at CC level being 1 mA at the 1^{st} cycle 320, the 20^{th} cycle 322, the 40^{th} cycle 324, the 60^{th} cycle 326, the 80^{th} cycle 328 and the 100^{th} cycle 330, according to one example. FIG. 4 shows a graph 400 illustrating I-V characteristics of the Ag/WTe₂/Pt device measured at CC level being 5 mA at the 1^{st} cycle 420, the 20^{th} cycle 422, the 40^{th} cycle 424, the 60^{th} cycle 426, the 80^{th} cycle 428 and the 100^{th} cycle 430, according to one example. FIG. 5 shows a graph 500 illustrating I-V characteristics of the Ag/WTe₂/Pt device measured with CC-free and self-limiting behaviour at the 1^{st} cycle 520, the 20^{th} cycle 522, the 40^{th} cycle 524, the 60^{th} cycle 526, the 80^{th} cycle 528 and the 100^{th} cycle 530, according to one example. The device did not need a high-voltage forming process, hence presenting forming-free resistive switching characteristics. This is attributed to the higher ionic conductivity of the WTe₂ metal chalcogenide solid electrolyte. The device shows bipolar resistive switching with the formation/rupture of an Ag CF during the SET/RESET process.

When the device undergoes a SET process under the low CC level (1 mA), an abrupt RESET is observed (see FIG. 3). Whereas for the higher CC levels (5 mA or no CC cases), the RESET becomes gradual as shown in FIG. 4 and FIG. 5, respectively. This is because when the CC level is limited to 1 mA, a smaller/weaker CF may be formed that may be ruptured abruptly. However, at higher CC levels, the CF grows stronger/thicker. A higher voltage may be needed to rupture it, thus providing a gradual RESET behavior. The device also exhibited self-compliance behavior as shown in FIG. 5, that is useful for passive crossbar array operation where a CC cannot be imposed. Once the stronger CF is formed during CC-free switching (abrupt SET at low voltage), the device self-limits the injection of Ag ions into the WTe₂ layer and thus the lateral growth of the CF.

It is believed that the good thermal conductivity of WTe₂ may have helped reduce local heating and prevent catastrophic failure by limiting the lateral growth of the CF upon SET. From first-principles simulation, the thermal conductivity of WTe₂ is found to be ˜9-20 W/m·K, higher than that of oxides such as ZrO₂, HfO₂, amongst others.

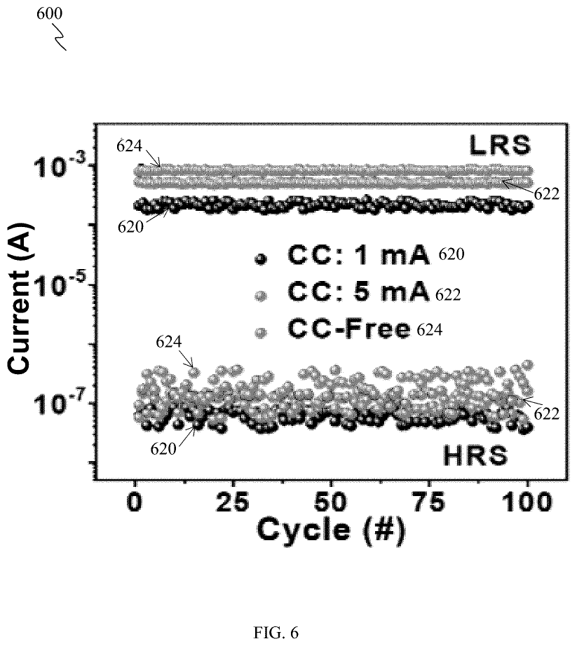

FIG. 6 shows a graph 600 illustrating a relationship between current and cycle number to reflect DC endurance characteristics of the Ag/WTe₂/Pt device at the CC level of 1 mA 620, 5 mA 622 and CC-free 624. In FIG. 6, the device shows repeatable switching at different CCs, demonstrating good DC endurance characteristics.

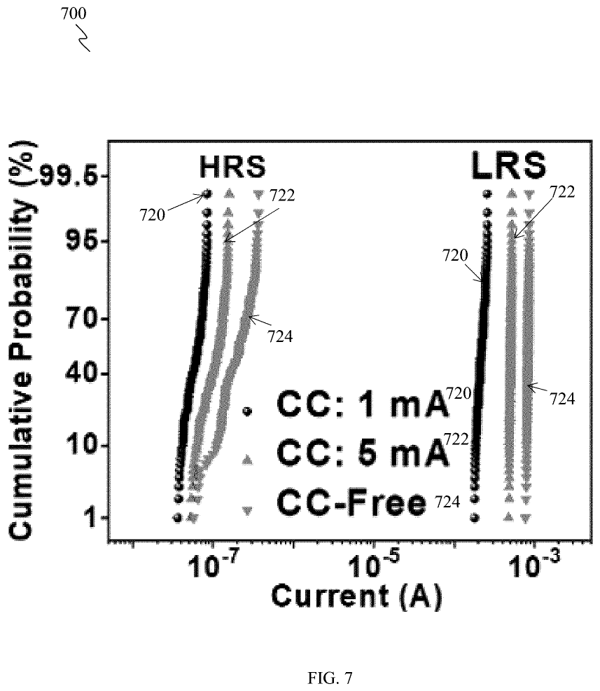

The C2C and D2D variability characteristics of the device, according to an example, are shown in FIGS. 7 to 10.

FIG. 7 shows a graph 700 illustrating the cumulative probability distribution of high resistance states (HRS) and low resistance states (LRS) of the device at the CC level of 1 mA 720, 5 mA 722 and CC-free 724. A uniform C2C distribution in HRS and LRS currents is observed for all CCs (see FIG. 7). Higher uniformity in the LRS currents may be due to the self-limiting behavior of the device during the SET process. Whereas, slightly higher variability in HRS may be due to the stochastic rupture of the CF during the RESET process.

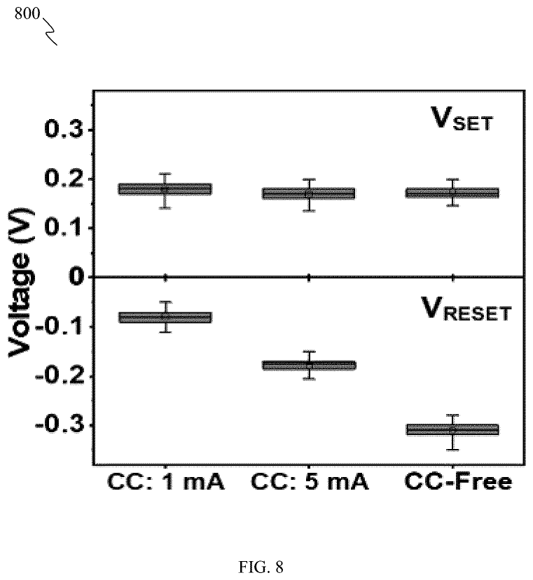

FIG. 8 shows a graph 800 illustrating box plots of VSET and VRESET for the device at the CC level of 1 mA, 5 mA and CC-free. The C2C distribution of VSET and VRESET in FIG. 8 depicts high uniformity in the switching voltages which is crucial for nonvolatile memory applications. A slight increase in the VRESET is observed as the CC increases. This increase in the VRESET supports the proposed mechanism on the strengthening of the CF at higher CC.

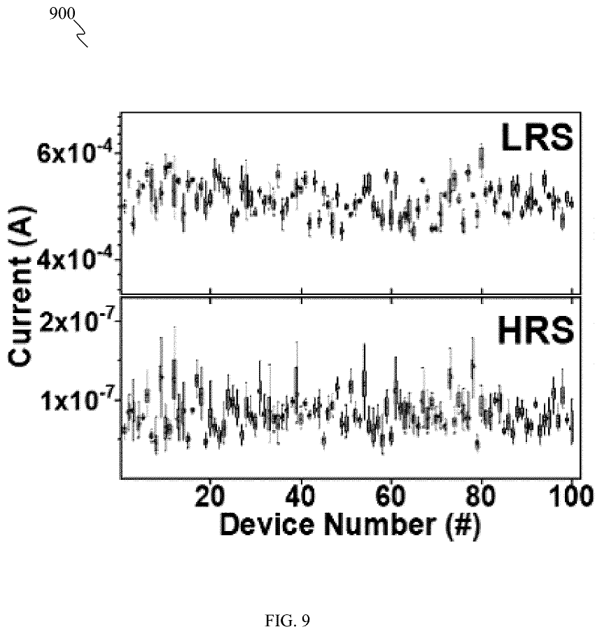

FIG. 9 shows a graph 900 illustrating plots of LRS and HRS currents from 100 devices to depict D2D variations. For the D2D variability measurements, the 100 randomly chosen devices were tested and each device was switched for 20 DC sweep cycles under a CC level of 5 mA. In the process, no failed device was encountered. The plots of HRS and LRS distribution in FIG. 9 show excellent uniformity in the current throughout all devices. The mean HRS and LRS currents were recorded as ˜82.4 nA and ˜0.51 mA with standard deviations of ˜24.5 nA and ˜0.03 mA, respectively.

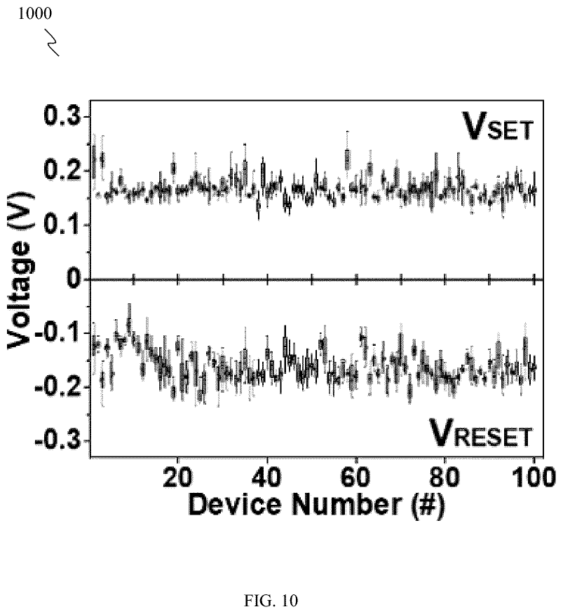

FIG. 10 shows a graph 1000 illustrating plots of VSET and VRESET from the 100 devices to depict D2D variations. Similarly to the observations in FIG. 9, a highly uniform D2D distribution of the switching voltages is presented by the device (see FIG. 10). The mean VSET and VRESET were measured as ˜0.17 V and ˜-0.16 V with standard deviations of ˜0.022 V and ˜0.031 V, respectively.

The D2D and C2C uniformity in the switching voltages allows easy and reliable programming of the memory cells in large crossbar arrays avoiding power and time-consuming program and verify steps.

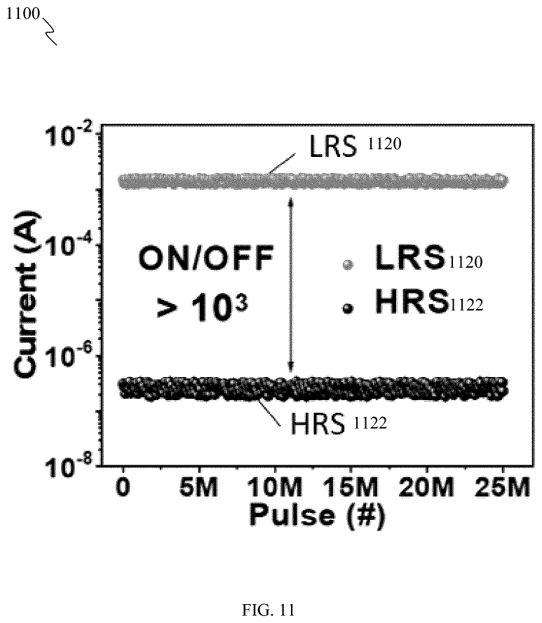

FIG. 11 shows a graph 1100 illustrating the relationships between LRS current 1120 and HRS current 1122 with respect to the number of pulses (pulse cycling for 2.5×10⁷ cycles) to depict the pulse endurance characteristics of the device, according to an example. The device exhibits excellent endurance characteristics for >2×10⁷ (>20 million) cycles without any apparent degradation of the memory window. The amplitude and width of the SET pulse were 1.5 V and 200 ns and those of the RESET pulse were −2 V and 200 ns, respectively. The difference in currents between ON/OFF is in the order of more than 103.

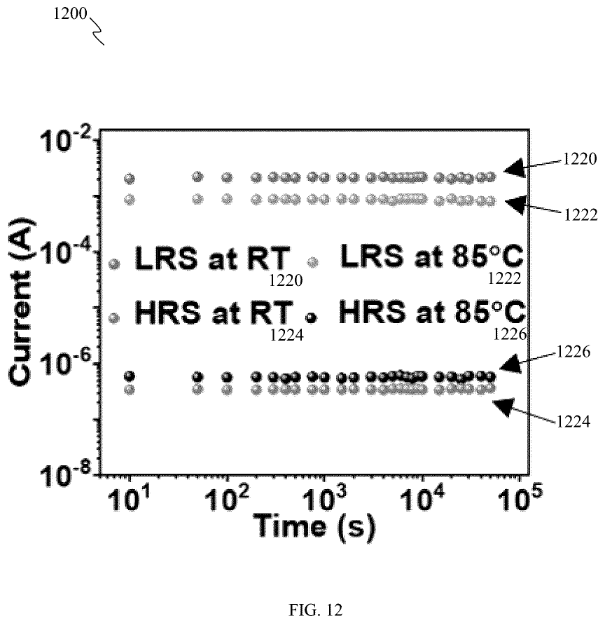

FIG. 12 shows a graph 1200 illustrating plots of LRS current at room temperature (RT) 1220, LRS current at 85° C. 1222, HRS current at RT 1224, and HRS current at 85° C. 1226 over time, to depict the retention characteristics of the device at these temperatures, according to an example. As seen in FIG. 12, the retention over 5×10⁴ seconds at 85° C. confirmed the nonvolatile nature of the resistance states. Higher temperature results in a slight reduction in LRS current, which supports the formation of metallic Ag CF in LRS. In addition, the retention failure time of the device was measured at higher temperatures (120° C., 150° C. and 180° C.), not shown in figures.

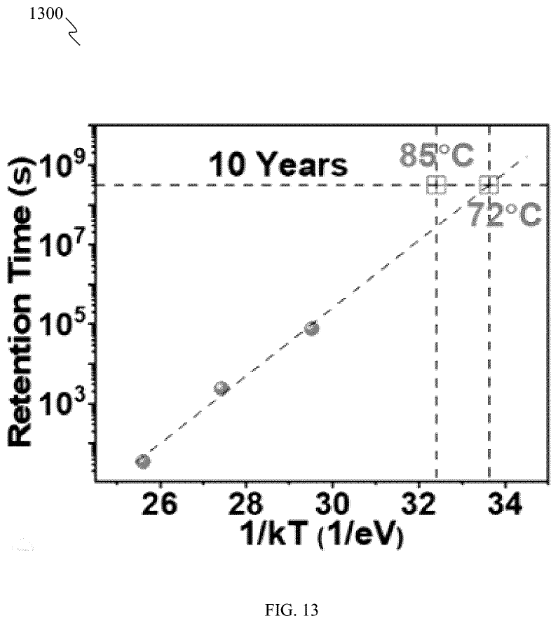

FIG. 13 shows a graph 1300 illustrating accelerated retention test to confirm 10 years retention at ˜72° C. More specifically, the graph 1300 is the extrapolation of Arrhenius plot showing that the Ag/WTe₂/Pt device is able to retain its memory for 10 years at ˜72° C. The 10-year period provides a comfortable margin that may be used to tradeoff for better endurance in the case of SCM application.

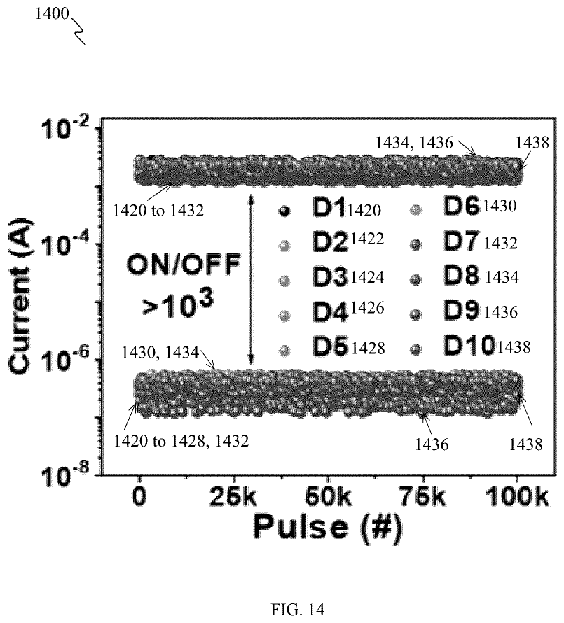

It is essential to be able to demonstrate high pulse endurance for multiple devices in judging the potential for practical application. FIG. 14 shows a graph 1400 illustrating the relationships between LRS current and HRS current with respect to the number of pulses to depict the pulse endurance characteristics of 10 sample devices (D1 1420, D2 1422, D3 1424, D4 1426, D5 1428, D6 1430, D7 1432, D8 1434, D9 1436, D10 1438). As seen in FIG. 14, the pulse endurance was measured in the 10 different devices 1420-1438 for 10⁵ cycles, and the difference in currents between ON/OFF for each of the devices 1420-1438 is in the order of more than 10³. Based on FIG. 14, it can be observed that the CBRAM device demonstrated a very low D2D variation and a highly reproducible pulse endurance.

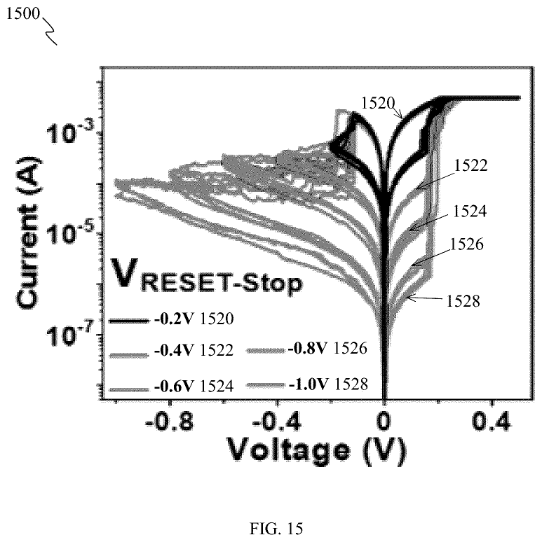

FIG. 15 shows a graph 1500 illustrating the I-V characteristics of the device presenting multilevel switching controlled by varying RESET sweep voltage, VRESET-Stop of −0.2 V 1520, −0.4 V 1522, −0.6 V 1524, −0.8 V 1526 and −1.0 V 1528. The gradual RESET behavior of the device at higher CC switching offers an opportunity for realizing multilevel switching for multibit data storage application. After the SET process at 5 mA CC, tuning the VRESET-Stop provided multiple intermediate resistance states (IRSs) demonstrating multilevel switching behavior, as shown in FIG. 15.

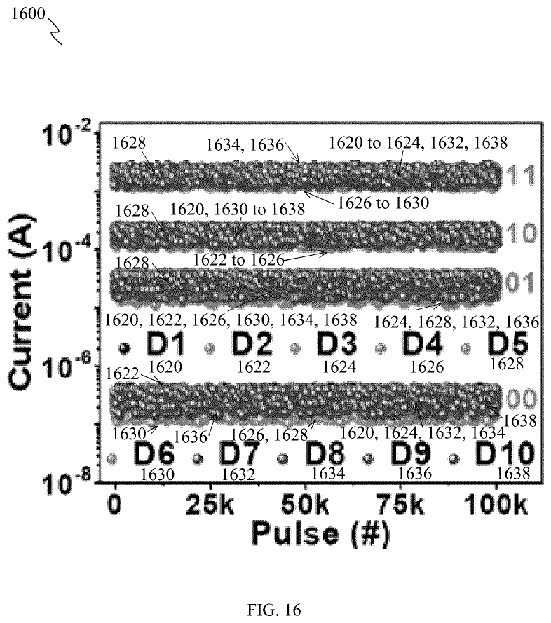

FIG. 16 shows a graph 1600 illustrating the relationships between the currents of multilevels with respect to the number of pulses to depict the pulse endurance characteristics of the multibit memory in 10 sample devices (D1 1620, D2 1622, D3 1624, D4 1626, D5 1628, D6 1630, D7 1632, D8 1634, D9 1636, D10 1638). As seen in FIG. 16, the pulse endurance of the multilevel switching was evaluated for 4 resistance states (2-bit). The amplitude and width of the SET pulse were fixed at 1.5 V and 200 ns. Whereas, the amplitude of RESET pulse was varied as −0.5 V, −1 V and −2 V to achieve the IRSs. The device exhibits highly repeatable endurance of 105 cycles for 2-bit memory measured in the 10 randomly selected devices.

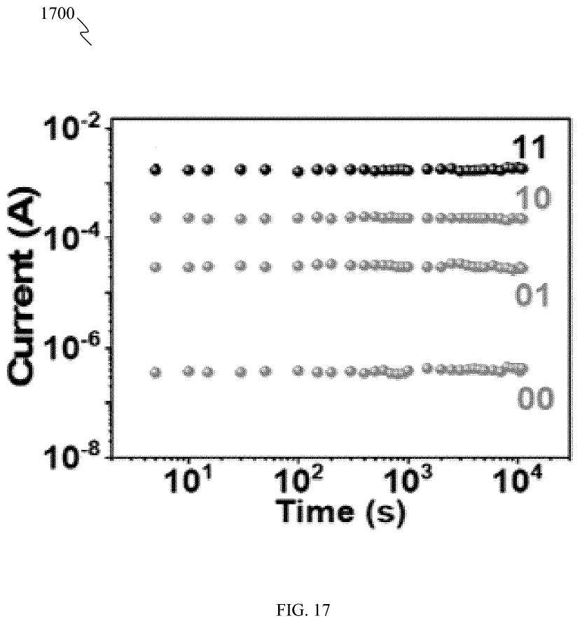

FIG. 17 shows a graph 1700 illustrating plots of the currents of multilevels over time, to depict the retention characteristics of the multibit memory states, according to an example. The resistance states may be converted from a high-current state to any intermediate state of a lower current by leveraging the gradual reset behavior. The retention of the multiple memory states for over 10⁴ seconds without any failure demonstrated nonvolatile multibit memory capability of the device, as shown in FIG. 17.

Like most CBRAM devices reported to-date, the Ag/WTe₂/Pt device exhibits a high switching current in the mA regime. While device scaling has helped brought the switching current of CBRAM devices down to sub-mA level, its effectiveness may be limited considering retention trade-off due to Rayleigh instability. The use of a large conventional select transistor to support the high switching current compromises scalability and integration density. Emerging selector technologies like insulator-metal transition selectors, ovonic threshold switching selectors, and Ag-based atomic selectors may provide a possible solution to this dilemma. These selectors have a high drive current and their similar physical structure aids compact integration.

The development of selector device (1S), that may also be chalcogenide based, may be integrated with the chalcogenide-based CBRAM device (1R), according to various embodiments and described above, to form a crossbar array of 1S1R devices.

High speed and low voltage pulse switching, at parameters below those presented earlier for the chalcogenide-based CBRAM device have been demonstrated.

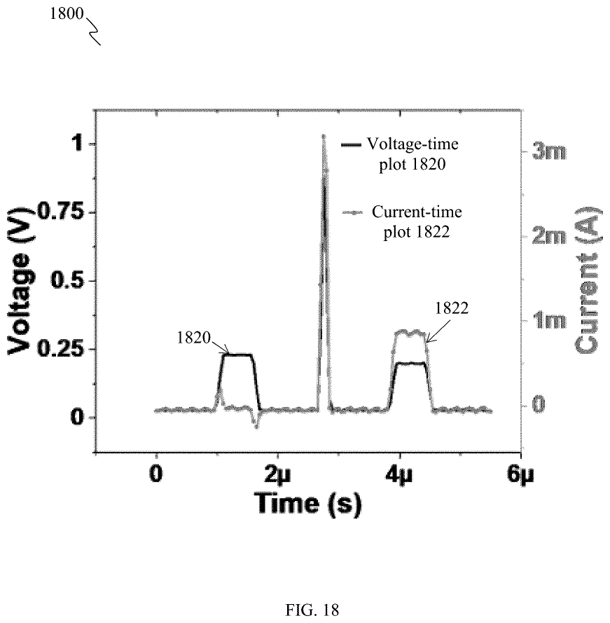

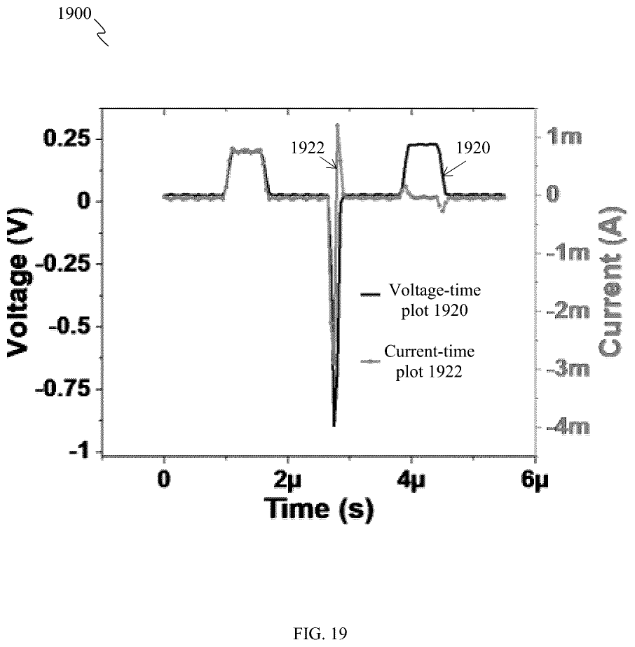

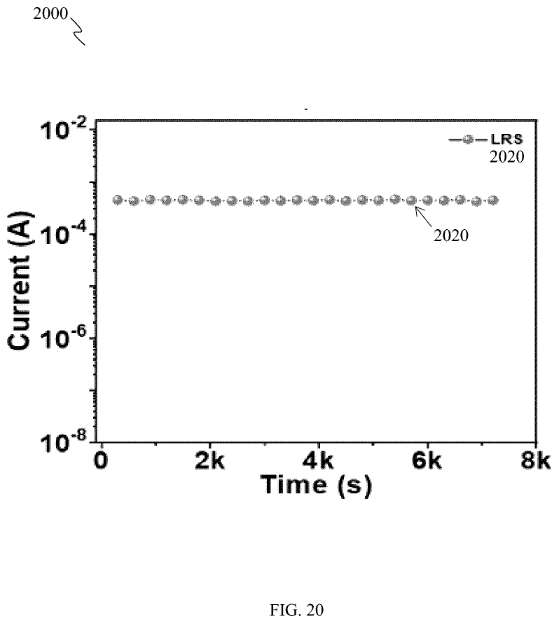

FIG. 18 shows a graph 1800 illustrating a voltage-vs-time plot 1820 and a current-vs-time plot 1822 of the Ag/WTe₂/Pt device, with SET being a 50 ns pulse with +1 V pulse amplitude, according to one example. FIG. 19 shows a graph 1900 illustrating a voltage-vs-time plot 1920 and a current-vs-time plot 1922 of the Ag/WTe₂/Pt device, with RESET being a 50 ns pulse with −1 V pulse amplitude, according to one example. FIG. 20 shows a graph 2000 illustrating the LRS current 2020 over time to depict the LRS retention of the Ag/WTe₂/Pt device after SET with a 50 ns pulse being read at 0.25V, according to one example.

The device presents non-volatile SET/RESET under a 50 ns pulse with +1/−1 V pulse amplitude and a memory retention that lasted at least 2 hours. These results provide confidence on attaining the goal of a new storage class non-volatile memory technology with DRAM-like operating voltage and speed.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

1. A device comprising:
a first electrode;
a second electrode arranged opposite to the first electrode; and
a transition-metal chalcogenide-based layer sandwiched between the first electrode and the second electrode, wherein the transition-metal chalcogenide-based layer is in direct contact with the first electrode and the second electrode.

2. The device as claimed in claim 1, wherein the transition-metal chalcogenide-based layer is an amorphous tungsten ditelluride (WTe₂) layer.

3. The device as claimed in claim 2, wherein the amorphous WTe₂ layer has a thickness ranging from 10 nm to 15 nm, or of about 12 nm.

4. The device as claimed in claim 1, wherein the first electrode comprises an inert metal.

5. The device as claimed in claim 1, wherein the second electrode comprises an electrochemically active metal.

6. The device as claimed in claim 1, wherein each of the first electrode and the second electrode has a thickness ranging from 50 nm to 100 nm, or of about 70 nm.

7. The device as claimed in claim 1, further comprising a substrate coupled to the first electrode.

8. The device as claimed in claim 7, wherein the substrate comprises a SiO₂/Si substrate.

9. The device as claimed in claim 7, further comprising an adhesion layer arranged between the substrate and the first electrode.

10. The device as claimed in claim 9, wherein the adhesion layer comprises titanium.

11. The device as claimed in claim 1, having a cell structure with a diameter of about 100 μm or less.

12. The device as claimed in claim 1, wherein the device comprises a chalcogenide-based conductive-bridge random access memory device.

13. A method for manufacturing a device, the method comprising:
providing a first electrode;
depositing a transition-metal chalcogenide material on the first electrode to form a transition-metal chalcogenide-based layer over the first electrode; and
depositing an electrically conductive material on the transition-metal chalcogenide-based layer to form a second electrode and to sandwich the transition-metal chalcogenide-based layer between the first electrode and the second electrode,
wherein the transition-metal chalcogenide-based layer is in direct contact with the first electrode and the second electrode.

14. The method as claimed in claim 13, wherein depositing the transition-metal chalcogenide material on the first electrode comprises depositing tungsten ditelluride (WTe₂) to form an amorphous WTe₂ layer over the first electrode.

15. The method as claimed in claim 14, wherein depositing the WTe₂ comprises performing radio frequency sputtering of WTe₂ on the first electrode.

16. The method as claimed in claim 13, further comprising coupling a substrate to the first electrode.

17. The method as claimed in claim 16, wherein coupling the substrate to the first electrode comprises depositing an adhesion layer on the substrate; and thermally evaporating another electrically conductive material over the adhesion layer to form the first electrode.

18. The method as claimed in claim 17, wherein depositing the adhesion layer comprises performing direct current sputtering of an adhesion material on the substrate.

19. The method as claimed in claim 13, wherein depositing the electrically conductive material on the transition-metal chalcogenide-based layer to form the second electrode comprises performing direct current sputtering of the electrically conductive material on the transition-metal chalcogenide-based layer.

20. The method as claimed in claim 13, further comprising forming a cell structure of the device using a metal shadow mask having a diameter of about 100 μm or less.
